(19) United States
(12) Patent Application Publication
(10) Pub. No.: US 2025/0008708 A1
(43) Pub. Date: Jan. 2, 2025

(54) POWER UNIT AND INDUCTION HOB WITH SUCH A POWER UNIT

(71) Applicant: E.G.O. Elektro-Gerätebau GmbH, Oberderdingen (DE)

(72) Inventors: Daniel Parker, Königsbach-Stein (DE); Andreas Richter, Leingarten (DE)

(21) Appl. No.: 18/664,369

(22) Filed: May 15, 2024

(30) Foreign Application Priority Data
Jun. 30, 2023 (DE) 10 2023 117 291.3

(51) Int. Cl. H05K 7/20; H05B 6/12

(52) U.S. Cl. CPC H05K 7/20918; H05B 6/1209; H05K 7/20945

(57) ABSTRACT

A power unit for an induction hob has a component carrier on which components to be cooled and a heat sink device therefor are arranged, a fan in the direction of the heat sink device, and an air duct from the fan to the heat sink device. The heat sink device is elongate and partially limits the air duct, wherein the latter has two or three outer walls and is formed thereby, said walls adjoining one another and being arranged at an angle to one another. The air duct extends along these walls and along the heat sink device, wherein it has at a starting area of the heat sink device a free area outside the heat sink device and between the outer walls. This free area becomes smaller in the longitudinal direction of the air duct away from the fan and in the direction of an end of the air duct, wherein it becomes zero by the end of the air duct. This allows air flowing along in the free area to be diverted into a heat sink further back in the air duct.

### CROSS-REFERENCE TO RELATED APPLICATIONS

This application claims priority to German Application No. 10 2023 117 291.3, filed Jun. 30, 2023, the contents of which are hereby incorporated herein in its entirety by reference.

### AREA OF APPLICATION AND PRIOR ART

The invention relates to a power unit, as is used in particular for an electrical appliance, such as for example an induction hob with a converter. The invention also relates to such an induction hob with a corresponding power unit. The power unit has a component carrier with components to be cooled thereon, in particular power semiconductors or IGBTs for a converter or for an inverter respectively. Furthermore, the power unit has a heat sink device having at least one heat sink with which the components to be cooled are in contact. A fan cools in turn the heat sink device, for which air flows in an air duct along the heat sink device.

A possible arrangement of such a power unit with heat sink and fan is known from CN 102769952 A1, in which the fan blows the expelled air directly onto the heat sink in order to cool it. The fan is even directly attached to the heat sink here.

An induction hob with cooling air routing is known from FR 2340513 A1. The latter is intended to additionally exploit a chimney effect.

### Object and Solution

The object underlying the invention is to provide a power unit as stated at the outset and an induction hob provided therewith, using which problems of the prior art can be solved, and enabling in particular the power unit to be constructed compactly and simply while ensuring the best possible cooling of the heat sink device and of the components to be cooled by it.

This object is solved by a power unit having the features of claim 1 and by an induction hob having the features of claim 20. Advantageous and preferred embodiments of the invention are the subject matter of further claims and are explained in greater detail below. Some of the features are described only for the power unit or only for the induction hob. They are however intended to apply, by themselves and independently of one another, both for a power unit and for an induction hob provided therewith. The wording of the claims is incorporated into the content of the description by express reference.

The power unit therefore has a component carrier on which components to be cooled are arranged, these being in particular the aforementioned power semiconductors, for example for a converter or an inverter. The power unit also has a heat sink device having at least one individual heat sink. The aforementioned components to be cooled are in contact with the heat sink device for heat transmission and/or for cooling them. Such a heat sink device advantageously consists of highly heat-conducting material, particularly advantageously of aluminum, in particular as an extruded section. The power unit has a fan with a fan outlet, wherein this fan outlet is pointing at least approximately towards the heat sink device. The cooling air moved by it is intended to cool the heat sink device as much as possible and remove the air heated as a result from the power unit, together with the absorbed heat. An air duct is provided for this air that leads away from the fan or from its fan outlet and above all towards the heat sink device. This is intended to achieve a selective routing of air so that the cooling effect for the heat sink device is maximized.

The heat sink device is elongate, and may in particular extend along a line or is elongate along this line, wherein this line extends from the longitudinal axis or parallel to the longitudinal axis of the heat sink device to the fan or its fan outlet. The fan with its fan outlet is thus preferably pointing towards the heat sink device. This may be further improved or reinforced by the air duct, wherein the air duct is at least partially limited by the heat sink device. It can thus also be ensured that the air flowing along in the air duct cools the heat sink device. The air duct has two or three outer walls adjoining one another and arranged at an angle to one another. These walls are advantageously designed planar or as flat parts. Particularly advantageously, they are at approximately right angles to one another, are at right angles, or are at an angle between 70° and 90° to one another. These may be different outer walls, as is explained in more detail in the following. They may also belong in one common housing, and in particular be connected to one another as one piece. The air duct thus extends along these two or three outer walls, i.e. along the heat sink device, wherein said duct also partially extends inside the heat sink device. This is therefore the extent of the air duct between the walls and the heat sink device.

In accordance with the invention, the air duct is formed or limited to the outside substantially by the said two or three outer walls and by the heat sink device. The air duct should here be at least partially closed to allow enough air to be routed to where it is required and needed. The air duct has at its initial area or at an initial area of the heat sink device a free area which is outside the heat sink device but still inside the said outer walls, or the free area is formed between the heat sink device and the said outer walls. The free area is therefore outside the heat sink device, but advantageously inside an area in which a substantial part of the air from the fan flowing along the air duct is flowing inside the heat sink device. This free area may take up between 5% and 50% of the entire air duct, preferably between 10% and 30%. The free area becomes smaller in the longitudinal direction of the air duct away from the fan and in the direction towards an end of the air duct. This may take place continuously, gradually or in a strictly monotonous gradual manner. The free area is largest at the start of the air duct, i.e. just behind the air outlet of the fan. The free area is smallest at the end of the air duct, preferably when the heat sink device too ends, and in particular it becomes zero, and no longer existent.

Due to this free area along the air duct, it is possible that some of the cooling air leaving the fan at the air outlet does not flow along or inside the heat sink device from the start, and is both slowed down and above all also heated up by the heat sink device. Instead, some of the air generated by the fan may flow in this free area partially or largely past the heat sink device and hence is not heated by said device. Only later, i.e. where the free area becomes smaller, can it re-enter or flow back into the heat sink device. As a result, cooler air may once again enter these areas, in particular in an area of the heat sink device which is at the rear when viewed from the fan, so that good and efficient cooling of the components present there is possible there too. Otherwise, mainly or only already heated air, or possibly even hot air, would arrive in that area of the heat sink device which is furthest away from the fan. This heated air could then cool the rear part of the heat sink device much less well, so that the components in contact with the heat sink device here are also cooled less well. Other possible solutions for this problem, for example the use of a further additional fan that supplies more air for cooling into areas further to the rear, may then also be dispensed with. Better and more selective air routing may be achieved by one of many possible embodiments of the air duct, and above all of the free area or of the constrictions of the air duct and of the free area.

In a possible embodiment of the invention, an air duct may be formed by the heat sink device, by a housing part under the heat sink device, and by an outer wall which is perpendicular or angled relative to the housing part, in particular as mentioned above. Preferably, it may be part of the same housing as the housing part. The free area is formed at least partially along this outer wall. It may be provided that the air duct is also closed to the top, i.e. on that side of the air duct opposite the housing part, by a cover which extends over the heat sink device, advantageously over the entire power unit. This would be the aforementioned three outer walls forming the air duct additionally with the heat sink device. The free area may extend over the entire height of the air duct, or have in the vertical direction a constant cross-section and hence fully extend along the outer wall.

In a first basic development of the invention, the heat sink device may be designed such that it does not itself change in its cross-section along the air duct and retains the same, i.e. constant, cross-section. The heat sink device then has no variation in its cross-section and becomes neither wider nor higher. In one embodiment of the invention, however, incisions or breaks provided in the direction transverse to the longitudinal direction of the heat sink device may be provided in said heat sink device. This is however not regarded as a cross-sectional change, since the heat sink device has the same cross-section in front of and behind each such incision or each such break. Incisions or breaks of this type can be used generally speaking for easier introduction of air into the heat sink device or for discharging air out of the latter.

In this development of the invention, the cross-section of the air duct narrows due to a change in the course of at least one of the outer walls along the air duct itself. The free area becomes narrower or smaller as a result. This may be provided in particular by a change in the course of at least one outer wall. Preferably, this may be an aforementioned outer wall, provided at the air duct opposite the heat sink device or limiting said air duct to the outside. At this cross-sectional change or constriction, some of the air expelled by the fan and flowing along the air duct outside the heat sink device is then forced or diverted into the heat sink device, thereby ensuring increased cooling.

In a possible embodiment of the invention, two or three such cross-sectional changes or constrictions of the free area of the air duct may be provided. Behind the last cross-sectional change or constriction, at least 90% of the air duct may be taken up, in particular completely or substantially completely, by the cross-section of the heat sink device. This means that air only flows inside or through the heat sink device. The heat sink device then reaches directly up to the aforementioned outer wall or at least a few millimeters in front of it.

It may be provided that a first constriction or cross-sectional change of the air duct is provided or arranged after around 20% to 45% of the length of the air duct away from the fan. This permits, starting in this area, more cold air to be introduced into the heat sink device for the first time. In a further embodiment of the invention, it may be provided that a final constriction of the air duct is provided after 70% to 90% of its length away from the fan. As a result, the last or rearmost area of the heat sink device may also be once again intensively cooled by the cooler air introduced there. Any further introduction after that would make little sense.

It may be provided that each cross-sectional change or constriction of the air duct reduces the free area by 25% to 50%. Two to four such cross-sectional changes or constrictions of the air duct may thus be provided advantageously, but not necessarily exclusively, so that cold air is once again diverted into the heat sink device at a corresponding number of places.

The aforementioned incisions or breaks are not essential nor particularly advantageous for this, but they may facilitate or improve the introduction of cooling air. Furthermore, they may ensure, by creating additional swirling, a more turbulent air flow and hence a better heat exchange. In particular, incisions or breaks of this type may be provided on a so-called base of the heat sink device, with which the aforementioned components to be cooled are substantially in contact. A base of this type is designed preferably solid, as the maximum amount of thermal energy is introduced here by the components to be cooled, and is first of all distributed towards the side into the remaining heat sink device, which is advantageously formed by ribs protruding from the base. Since this base is usually substantially closed, it is possible here due to the incisions or breaks to create a good possibility for discharging the air in this area out of the heat sink device. The point of this may be that this air is then passed to even more areas or components on the component carrier, which are also to be cooled but are outside the aforementioned air duct.

In a second basic development of the invention, the cross-section of the entire air duct may remain the same, and here it is the cross-section of the heat sink device that changes, not the course of the walls outside it, as in the previously described first development of the invention. The heat sink device may thus be designed narrower, at an initial area facing the fan or situated closest thereto, than is the case further away from it and may have a reduced cross-section. In particular, the cross-section may be reduced by 10% to 50%. In particular, it may be provided that around 10% to 30% of the length of the heat sink device are lower in cross-section at the initial area. Due to the then increasing cross-section, the free area of the air duct is reduced or becomes smaller towards the outer walls, enabling the previously described effect of cooler air being forced into the heat sink device over the longitudinal course of the air duct. However, this is not achieved by changing the course of the outer walls, but by a change in the course of the heat sink device itself. Either the cross-section of the heat sink device can increase in the direction away from fan and along the air duct, or alternatively a heat sink device with constant cross-section may be pointing slightly obliquely towards the actual longitudinal direction of the air duct and thus obliquely to a wall of the air duct opposite the heat sink device. This air duct and hence also the free area continuously become narrower, so that all air is diverted into the heat sink device up to the end of the air duct. By designing the outer walls of the air duct straight, a particularly simple embodiment of the air duct may be achieved.

In a further embodiment of the invention, it may be provided that the heat sink device has several partial heat sinks having the same or identical cross-section, wherein these partial heat sinks are arranged one behind the other in the longitudinal direction of the air duct. This may therefore be an enhanced embodiment of the aforementioned variation in which incisions or breaks are provided in the heat sink device. A space may be provided between at least two such partial heat sinks, in particular between all partial heat sinks, to form an intermediate area. No heat sink is provided in this intermediate area. Such an intermediate area may have a length between 1% and 10% of the length of the entire heat sink device, such that these intermediate areas or distances between two consecutive partial heat sinks are relatively small. In a possible further embodiment of the invention, at least two partial heat sinks may have different lengths along the longitudinal direction of the air duct. This allows partial heat sinks to be designed preferably closer towards the fan than partial heat sinks with a greater spacing. Those components which become hottest in normal operation or in very frequent operation may then also be arranged on the longer partial heat sinks. They then have the larger partial heat sinks available to them.

In an alternative embodiment to providing several partial heat sinks, a very long heat sink, and in particular a single and continuous heat sink, may be provided for the heat sink device. In this heat sink, at least one recess extending inwards from the outside is provided, which can take up between 10% and 30% of the cross-section of the heat sink device. Advantageously, such a recess is provided on that side of the heat sink device or heat sink facing the component carrier or having in the heat sink an aforementioned solid base or a solid base element, wherein standard ribs then protrude from this base or from this base element. A break in the heat sink may therefore also be provided, corresponding to an aforementioned intermediate area, in such a recess created in the heat sink using a material-removing process. Inside it, cooling air may be discharged in the direction of the component carrier or components present thereon which are also to be cooled, without an excessively complicated course of the air duct or a further fan being necessary.

Air discharge means may be provided to improve this discharge of air out of the heat sink device, i.e. out of an intermediate area between two partial heat sinks or out of a recess in a single heat sink. These may thus effect a selective discharge of air. It is possible that such air discharge means are designed in the manner of a flap or in the manner of an air guide vane, preferably having a geometry similar to an aerodynamic wing. They engage in the cross-section of the air duct inside the heat sink device, i.e. as a rule between the areas of the ribs in the heat sink device. They can thus discharge some of the air flowing along. In doing so, they may discharge the air in the direction of further areas to be cooled and/or components on the component carrier. They may then be either designed directly elongate for better air routing, or have/form further air guide ducts. Depending on how far these air discharge means engage in the air duct, they discharge more or less air out of the heat sink device. A major part of the effect of the described arrangement is that warm air is guided away from a base or from a solid section of the heat sink device, and hence less heated air may be initially diverted away from the following partial heat sinks. An additional effect is obtained due to a negative pressure arising behind each air discharge means, which in turn draws cooler air out of the free area or out of the air duct, but also leads to turbulence and for that reason ensures an improved heat exchange.

In an advantageous development of the invention, it may be provided that the air discharge means are designed movable or adjustable in terms of the extent to which they engage in the cross-section of the air duct inside the heat sink device. It is thus possible to influence how much air they discharge. They are many possibilities for movability or adjustability of the air discharge means. According to one simple possibility, they may be designed thermally triggerable and self-adjustable. This is done possibly automatically, although not in a controlled manner. To do so, the air discharge means may preferably consist of or contain a bimetal. Being temperature-dependent, they can thus change shape and hence engage more or less far in the air duct. They may be thermally influenced here above all by those areas or components on the component carrier which they are also intended to cool by routing air to them. This is a very simple possibility which requires no control or regulation effort and also no controlled actuators. Air discharging means of this type may thus be elongated tabs.

According to another possibility, the air discharge means may have an actuator using which they can be adjusted. This may advantageously be an electromagnetic or an electric motor actuator, permitting a simple embodiment and at the same time good control or influencing. These actuators may be triggered by the temperature recorded at the further areas or components to be cooled.

In a similar form as for the air discharge means previously described, an adjustable air intake device may be provided on an outer area of the heat sink device, however completely independently thereof, i.e. advantageously towards one of the outer walls. This may be designed in particular in the manner of an air guide vane or have air guide vanes of this type. Advantageously it may be opposite that area of the heat sink device with which the components to be cooled are in contact, i.e. in particular an aforementioned base or base element. Such an air intake device may be used to change or reduce a free area of the air guide duct outside the heat sink device. An air intake device may thus be movable between two positions. In a first position, the air intake device projects into the free area and also into the heat sink device or up to the latter. In this way, air flowing outside the heat sink device and along the air duct may be diverted into the heat sink device. This is then the aforementioned reduction or elimination of the free area. In a second position, the air intake device may reach less far or even not at all into the free area, or reach the heat sink device such that it then additionally introduces only a little air or even none at all into the heat sink device. The first position and the second position may advantageously each be end positions of a movement path of the air intake device. The air intake device may be designed in different ways for such a movement. According to one possibility, it may be designed thermally triggerable and self-adjustable depending on the temperature, as has been previously described. A bimetal actuator, which may contain or consist of a bimetal, may be used for this. The air intake device or an air guide vane substantially forming the latter may also itself be designed largely bimetal or containing a bimetal. A bimetal actuator may also consist of a bimetal and an additional heating element if heating by the heat sink device itself is not enough for a sufficient deflection of the bimetal. The bimetal may thus be more greatly deflected by additional heating. Advantageously, ceramic heating elements may be used for this, particularly advantageously with a thick-film heating element on a flat ceramic carrier.

In an alternative embodiment of the invention, an aforementioned electromagnetic or electric motor actuator may in turn be provided which must then be directly controlled and additionally supplied with electric energy. It may be controlled by means of temperature sensors provided, or alternatively a control for the actuator may obtain information calling for a greater air intake in another way.

In an advantageous embodiment of the invention, the outer wall and preferably also the mentioned housing part underneath the heat sink device may each be formed by a wall area of a housing for the power unit. The power unit may then be arranged in this housing, and possibly also other elements of the electrical appliance for which the power unit is provided. If the power unit is an integral part of an induction hob in accordance with the invention and as mentioned at the outset, the power unit may advantageously extend along an outer border area of the housing. It may thus be advantageously arranged at the induction hob, in particular underneath a hob plate thereof, as is generally known per se. A cover or similar, which as previously described forms a third outer wall limiting the air duct at the top, may then be provided on the housing.

These and further features are revealed in the description and in the drawings as well as in the claims, wherein the individual features can each be realized singly or severally in the form of sub-combinations in one embodiment of the invention and in other fields, and can represent embodiments advantageous and protectable per se, for which protection is claimed here. The subdivision of the application into individual sections and subheadings does not limit the general validity of the statements made thereunder.

### BRIEF DESCRIPTION OF THE DRAWINGS

Further advantages and aspects of the invention can be found in the claims and in the description of exemplary embodiments of the invention that are explained in the following on the basis of the figures. The drawing shows in:

FIG. 1 a simplified sectional view from the side through an induction hob in accordance with the invention with a power unit in accordance with the invention,

FIG. 2 a plan view onto the power unit in accordance with the invention from FIG. 1 with component carrier, heat sinks, fan und air duct,

FIG. 3 a sectional view through the power unit from FIG. 2 in the front area of the air duct,

FIG. 4 a sectional view similar to FIG. 3 in the rearmost area of the air duct,

FIG. 5 an enlarged representation of a plan view onto the power unit from FIG. 2 illustrating an additional air discharge flap between two heat sinks in an inactive position,

FIG. 6 a representation according to FIG. 5 with the air discharge flap in an active position,

FIG. 7 a representation of a variant power unit similar to FIG. 2 with differently designed air duct and air intake flaps between the heat sinks and the air duct, and

FIG. 8 a further variant of a power unit similar to FIG. 2 with an air duct similar to FIG. 7 and heat sinks offset to the rear.

### DETAILED DESCRIPTION OF THE EXAMPLES

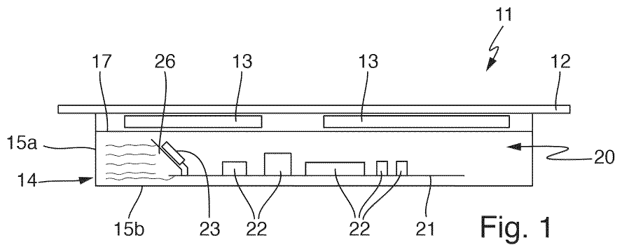

FIG. 1 shows an induction hob 11 in accordance with the invention in section. The induction hob 11 has a standard hob plate 12. Induction heating coils 13 are pressed onto its underside. The main functional structural units of the induction hob 11 are arranged in a housing 14 with housing outer wall 15a and housing floor 15b. The housing 14 may advantageously consist of plastic, offering great freedom and variety in its design. The housing 14 is provided at the top with a cover 17 on which the induction heating coils 13 may be placed.

A power unit 20 in accordance with the invention is arranged in the housing 14. The power unit 20 has a planar component carrier 21, in particular a printed circuit board on which a variety of components 22 are arranged. IGBTs 23 or rectifiers 23′ are arranged above all in the left-hand area of the component carrier 21. These are the power semiconductors mentioned at the outset, which become warm or hot during operation of the induction heating coils 13. For that reason, they are cooled in a known manner by being in contact with heat sinks 26. These heat sinks 26 are explained subsequently in detail. The heat sinks 26 are in turn cooled by air along an air duct 33 extending on the left in FIG. 1, as shown in the following.

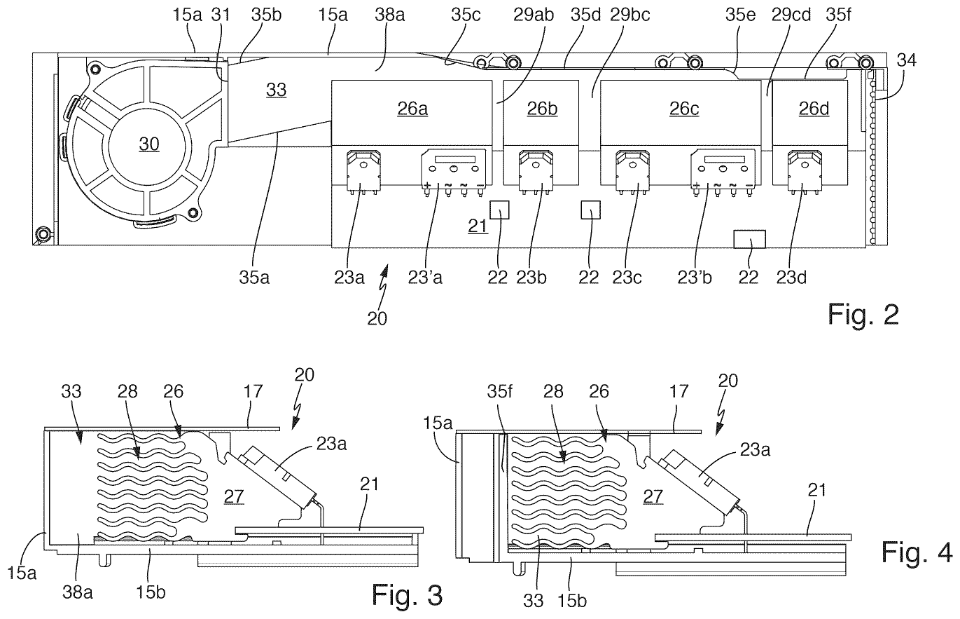

FIG. 2 shows a plan view onto a power unit 20 in accordance with the invention in the housing 14. The power unit 20 is arranged according to FIG. 1 close to the housing outer wall 15a. The one part of the component carrier 21 on which four IGBTs 23a, 23b, 23c and 23d are arranged is readily discernible. They are arranged in a line. Rectifiers 23′a and 23′b are arranged on the right next to the IGBTs 23a and 23c respectively. Each of the IGBTs 23a to 23d is provided with its own heat sink 26a to 26d. The heat sinks 26a and 26c with the rectifiers 23′a and 23′b on the right next to the IGBTs 23a and 23c are designed longer for higher cooling capacity and stronger cooling.

Furthermore, some of the aforementioned further components 22 are arranged on the component carrier 21. These should if possible also be cooled later on, as is explained in the following. There are differing distances 29ab, 29bc and 29cd between the heat sinks 26a to 26d. These are used for simplified introduction of cooling air, as is explained in more detail in the following.

At the rear area of the heat sinks 26a to 26d up to the housing outer wall 15a is an air duct 33, starting on the left, wherein a radially operating fan 30 known per se with a fan outlet 31 is arranged here. The fan outlet 31 faces exactly in the direction of the air duct 33 and in the direction of the heat sinks 26a to 26d. On the right the air duct 33 has an outlet 34 from the housing 14, advantageously provided with a grille, as is usual per se. An air guide vane 35a is provided on the left at the start of the air duct 33 directly adjoining the lower part of the fan outlet 31. A short air guide vane 35b is provided opposite to it. The air flowing along and inside the air duct 33 then hits the left-hand area of the first heat sink 26a. Towards the rear, the air duct 33 is formed by the housing outer wall 15a. This housing outer wall 15a has in practice a distance of 7 mm to 20 mm from the heat sink 26a, thereby forming a free area 38a as previously explained. From around the middle, and opposite the rear area of the heat sink 26a, a further air guide vane 35c is arranged which extends inwards from the inner side of the housing outer wall 15a and so constricts the air duct 33. This constriction ends just before the space 29ab between the heat sinks 26a and 26b, and starting from this air guide vane 35c or from the constriction formed thereby a following free area 38b is considerably smaller than the free area 38a. It may be in particular 0.5 cm to 1 cm. The air duct 33 is here limited at the rear by an air guide vane 35d which extends parallel to the rear side of the heat sinks 26b and 26c at a constant distance thereto. A free area 38c similar to the free area 38b is thus provided behind the heat sink 26c. It is then followed either by a further air guide vane 35e, or the existing air guide vane is bent again, thereby again greatly constricting the air duct 33, as a result of which the free area 38c too becomes smaller or in effect disappears. The rear wall of the air duct 33 is then formed by an air guide vane 35f which runs just behind the rearmost heat sink 26d, such that there is actually no longer a free area here. Then the air duct 33 continues to the outlet 34.

It is even easier to trace the course of the air duct 33 or the width of the free areas in FIGS. 3 and 4 with their respective sectional views. FIG. 3 shows a section through the leftmost or first IGBT 23a. It is obliquely in contact with the heat sink 26, and in particular with a solid base 27 of the latter. From this base 27, ribs 28 extend leftward, and are designed in corrugated form to increase their surface area for a better heat exchange and hence for a better cooling effect of the IGBT 23a. The heat sink 26 is advantageously designed of aluminum, particularly advantageously made using an extrusion method. The individual heat sinks 26a to 26d according to FIG. 2 may then be cut or sawn from one long section to the length required. The heat sink 26 is thus fitted from the left onto an outer edge of the component carrier 21 and may thus be firmly connected thereto using screws or other fastening possibilities. The heat sink 26 thus extends with narrow spacing below the cover 17 and above the housing floor 15b. Leftwards in FIG. 3, corresponding to rearwards in FIG. 2, there is a distance from the ends of the ribs 28 and hence of the heat sink 26 to the housing outer wall 15a, and this distance corresponds to the free area 38a and forms a part of the air duct 33. The greater width of the air duct 33 extends through the individual ribs 28.

FIG. 4 shows a corresponding sectional view through the rightmost or rearmost IGBT 23d. It may be discerned that the heat sink 26d has the same cross-section as the heat sink 26a from FIG. 3. The housing outer wall 15a too is still the same, with only the previously explained air guide vane 35f being present, which extends at a very short distance from the ribs 28 or their free ends. Hence there is no longer a free area here, the air duct 33 is narrower and passes only through the ribs 28.

As may be readily discerned from an overall view of FIGS. 2 to 4, some of the air introduced by the fan 30 into the air duct 33 right at the start will always flow through the ribs 28 of the heat sinks 26a to 26d and cool them. A significant proportion of the air will however also flow along the free areas 38a, 38b and 38c, i.e. past the heat sinks 26a to 26c. This air is then still cool. Due to the first constriction at the air guide vane 35c with reduced free area 38b, some of this air is additionally diverted or forced into the heat sink 26b and can cool the latter even better, as this air is still cool. In the reduced free areas 38b and 38c, a still significant part of the air can flow past the heat sinks 26b and 26c and remain cool. At the further constriction of the air duct 33 formed by the air guide vane 35e, thereby eliminating the free area 38c, this air too is diverted into the heat sinks, i.e. into the end of the heat sink 26c and above all additionally into the heat sink 26d. The latter may therefore also be additionally cooled, since its cooling effect is per se lower. This is because the air flowing through the ribs 28 inside the air duct 33 has already been warmed up by the three heat sinks 26a to 26c before it, so that their cooling effect is considerably lower.

Due to the spaces 29ab, 29bc and 29cd the air may be introduced readily and additionally from above into the heat sinks or their ribs 28. Furthermore, the corresponding power semiconductors may be better decoupled thermally in this way.

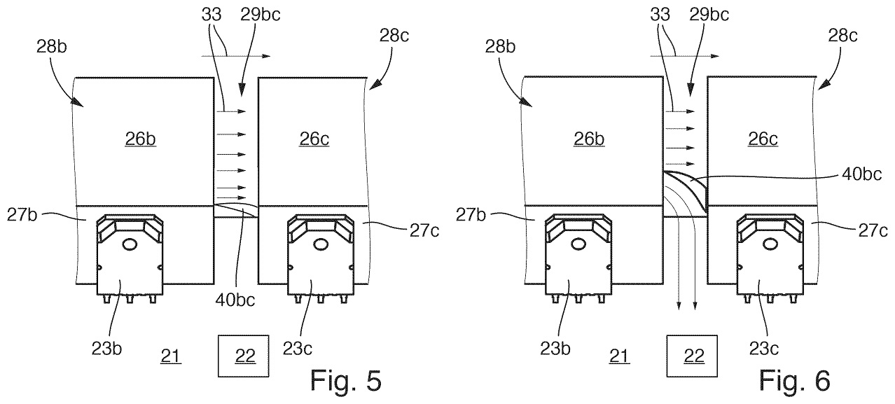

FIGS. 5 and 6 show a possibility for air to be discharged using a space 29bc between the heat sinks 26b and 26c, and to be guided to a component 22, also to be cooled, on the component carrier 21. To do so, an air discharge flap 40bc made of bimetal is firmly mounted by its right-hand end either to the component carrier 21 or advantageously to the left-hand side of the heat sink 26c. This air discharge flap 40 may extend, with reference to FIGS. 3 and 4, over part of the height between the component carrier 21/housing floor 15b and the cover 17, possibly also over the entire height. The air discharge flap 40 made of bimetal may be designed such that the area with a higher expansion faces the component 22 and is present on the other side of the area with a lower thermal expansion. FIG. 5 shows a position or setting of the air discharge flap 40 at low temperature, in the so-called inactive position. It is located substantially between the two bases 27 of the heat sinks 26b and 26c. As a result, it does not guide any air out of the air duct 33 provided here in the space 29bc, which is why it is inactive.

If the entire device becomes warmer, and in particular of course the heat sinks 26b and 26c, such that as a rule the component 22 too has to be cooled more, then the air discharge flap 40 bends/deforms and slightly rotates clockwise about its fastening point. As a result, it projects, in this so-called active position, further into the air duct 33 and above all in front of the ribs 28 of the right-hand heat sink 26c. It may thus discharge part of the cooling air, shown by the arrows, between the bases 27 of the two heat sinks 26b and 26c and through to the component 22. The latter may thus also be cooled somewhat. Such air discharge means designed in the form of an air discharge flap 40 made of bimetal have of course the major advantage that they do not need any additional actuators like the electric motors or electromagnets mentioned at the outset. Their design allows their temperature dependence and their effect to be set very well.

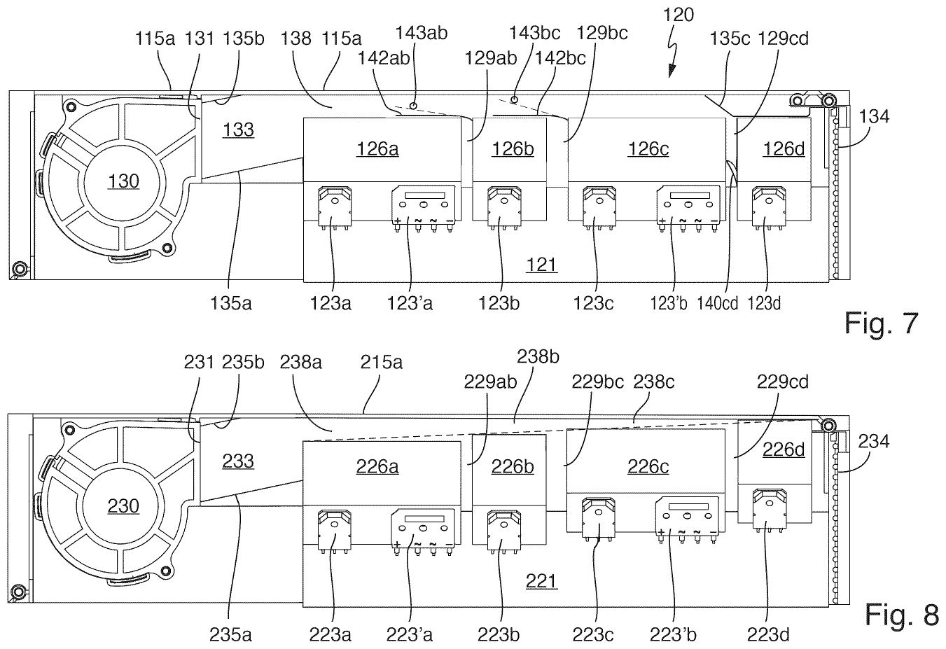

FIG. 7 shows a variation of a power unit 120, wherein this power unit 120 is obviously very similar to the power unit 20 from FIG. 2. A first substantial difference is that the upper wall of the air duct 133 behind the air guide vane 135b is formed over a very long area only by the outer wall 115a, i.e. as far as the area approximately in the middle above the third heat sink 126c. It is only from here that another air guide vane 135c is provided, which constricts the air duct 133 by reducing the free area 138. Here the air guide vane 135c extends up to the rear face of the fourth heat sink 126d, similarly to the air guide vane 35e in FIG. 2. As a result, the entire air flowing along in the air duct 133 outside the heat sink 126 is introduced no later than here into this final heat sink 126d.

However, to continue to provide additional air for cooling the heat sinks 126b and 126c, two air intake flaps 142ab, 142bc are provided too. They may in principle be designed similarly to the air discharge flaps 40 in FIGS. 5 and 6. Furthermore, they may also be designed such that they are fastened at the right-hand end and rotate to the right, i.e. clockwise, as the temperature increases. If they are thermally connected to the respectively associated heat sink, onto which they can guide air in the rightward-rotated state, then they can introduce air influenced by its temperature, i.e. in line with demand. To do so, the air intake flap 142ab may be thermally coupled to the heat sink 126b, in particular be fastened thereto. If this heats up greatly, the air intake flap 142ab rotates into the position shown in FIG. 7. A stop 143ab that prevents any further rotation is provided here. Otherwise it might be the case that the air intake flap 142ab reaches very far into the air duct 133 or is in contact with the housing outer wall 115a and thus impairs the further passage of air along the free area 138. The air intake flap 142ab thus represents a constriction of the free area, which is the core of the invention, even though this constriction is only in some areas.

The second air intake flap 142bc may be designed in the same way and attached to the third heat sink 126c as well as thermally coupled thereto. It too has a stop 143bc which is arranged slightly closer to the housing outer wall 115 than the stop 143ab. This stop 143bc still allows air to flow along in the free area 138 and then be introduced into the fourth heat sink 126d right at the back thanks to the air guide vane 135c. Behind the air guide vane 135c the free area 138 no longer exists. The effect of the air guide vane 135c and of introducing cool air from the free area 138 into the fourth heat sink 126d may also be assisted by an air discharge flap 140cd between the third heat sink 126c and the fourth heat sink 126d, and having a function as described for FIG. 6.

FIG. 8 shows yet another alternative embodiment of a power unit 220 in accordance with the invention. The air duct 233 here extends in principle similarly to as shown in FIG. 7, i.e. at the start with air guide vanes 235a at the bottom and 235b at the top. The air duct 233 is then however formed at the rear exclusively by the housing outer wall 215a, and is therefore straight. A third air guide vane 235c, which guides the air to a grille-like outlet 234, is only provided right at the rear.

A constriction of the free area 238 increasing from left to right is achieved here by the heat sinks 226a to 226d having a greater extent towards the rear. This is shown by way of example for the heat sink 226b in comparison with the heat sink 226a; it extends a few millimeters further to the rear. Since it starts at the front at the same point, the heat sink 226b is longer overall in the direction of the housing outer wall 215a and can thus have longer ribs. This could also be the case for the heat sinks 226c and 226d in the same way, in that they can each have longer ribs step by step. The long ribs of the rightmost heat sink 226d are then in contact with the housing outer wall 215a.

Alternatively, the heat sinks may, as shown for the heat sinks 226c and 226d, have the same cross-section but are offset rearwards together with their IGBTs and rectifiers on the component carrier 221. With an embodiment of this type, all four heat sinks 226a to 226d could thus have an identical cross-section, i.e. be sawn to length from an extruded section, as was explained at the outset. Each of them is moved rearwards only step by step, in order to reduce the free area 238 in the air duct 233, which is still large at the start. This also allows additional air to be introduced into the heat sinks 226 which have been offset step by step to the rear.

Yet another alternative embodiment that is readily conceivable is shown with the dashed contour of the heat sinks 226 close to the housing outer wall 215a. The heat sinks 226 can extend here obliquely to the rear. Their rear edges facing the housing outer wall 215a are thus no longer parallel to it, but somewhat oblique at a slight angle of 3° to 7°. The heat sinks 226 are then also fitted obliquely on the component carrier 221 to match this dashed oblique line. In this way, they achieve a continuous reduction of the free area 238 along the air duct 233 and away from the fan 230. This may easily be achieved for example in that one side or edge of the component carrier 221, which in accordance with FIGS. 3 and 4 engages in a recess at the bottom on the base 27 of the heat sink 26, is designed correspondingly oblique. This alternative embodiment too has the advantage that identical heat sinks may be used, or heat sinks from the same section.

In yet another embodiment of the invention not shown here, the fourth heat sink right at the end and at the maximum distance from the fan is not needed and so is not provided. As a result, here too the entire air duct or free area is not needed, and all the air coming from the fan should therefore flow into the heat sink device right from the start. The air duct may then remain closed, for example by a further air guide vane similar to the air guide vane 35b from FIG. 2 being provided on the left at the first heat sink 26a. Alternatively, the air guide vane 35b itself can lead from the fan 30 to the top left corner on the first heat sink 26a. In an advantageous development, the three heat sinks 26a to 26c may also be closed at the rear end so that no cooling air exits here. This can be achieved by a greatly lengthened air guide vane 35b which then extends from the fan 30 to the right-hand end of the third heat sink 26c. It is in contact at the rear with the heat sinks 26a to 26c like the air guide vane 35f with the heat sink 26d in FIG. 2.

1. A power unit, wherein said power unit has:
a component carrier, wherein components to be cooled are arranged on said component carrier,
a heat sink device, wherein said components to be cooled are in contact with said heat sink device for heat transmission,
a fan with a fan outlet, said fan outlet pointing towards said heat sink device,
an air duct from said fan or from said fan outlet to said heat sink device,
wherein
said heat sink device is elongate,
said air duct is partially limited by said heat sink device,
said air duct has two or three outer walls adjoining one another and arranged at an angle to one another,
said air duct extends along said two or three outer walls along said heat sink device,
wherein:
said air duct is formed or limited substantially by said two or three outer walls and by said heat sink device,
said air duct has an initial area and an end, and at said initial area of said heat sink device a free area is provided outside said heat sink device and between said outer walls or facing said outer walls, wherein said free area becomes smaller in a longitudinal direction of said air duct away from said fan and towards said end of said air duct.

2. The power unit according to claim 1, wherein said air duct is formed by said heat sink device, by a housing part under said heat sink device, and by an outer wall being perpendicular or angled relative to said housing part and has at least partially said free area to said heat sink device.

3. The power unit according to claim 1, wherein said air duct is closed to a top by a cover being provided over said heat sink device.

4. The power unit according to claim 1, wherein said heat sink device itself has no change in its cross-section along said air duct and retains said cross-section, wherein said cross-section of said air duct is constricted by a change in a course of at least one of said outer walls along said air duct and said free area becomes narrower or smaller, and wherein said course of said at least one outer wall changes.

5. The power unit according to claim 4, wherein two said cross-sectional changes or constrictions of said free area of said air duct are provided, wherein at least 90% of said air duct behind said last constriction is taken up by said cross-section of said heat sink device.

6. The power unit according to claim 4, wherein a first constriction of said air duct is provided after 20% to 45% of a length of said air duct away from said fan, wherein a final constriction of said air duct is provided after 70% to 90% of a length of said air duct away from said fan.

7. The power unit according claim 4, wherein each constriction of said air duct reduces said free area by 25% to 50%.

8. The power unit according to claim 1, wherein said cross-section of said air duct remains the same outside said heat sink device, wherein said heat sink device is designed narrower, at an initial area facing said fan, with a reduced cross-section, than is the case further away from said fan.

9. The power unit according to claim 8, wherein said walls of said air duct are straight outside said heat sink device itself.

10. The power unit according to claim 1, wherein said heat sink device is elongate along a line extending to said fan or to said fan outlet.

11. The power unit according to claim 1, wherein incisions or breaks are provided in said heat sink device in a direction transverse to said longitudinal direction of said heat sink, wherein said incisions or said breaks do not change said cross-section of said heat sink device.

12. The power unit according to claim 1, wherein said heat sink device has several partial heat sinks, each said partial heat sinks having an identical cross-section and being arranged one behind the other in a longitudinal direction of said air duct, wherein a space is provided to form an intermediate area between at least two said partial heat sinks, wherein said intermediate area has a length between 1% and 10% of a length of said entire heat sink device.

13. The power unit according to claim 12, wherein air discharge means are provided in said space or said intermediate area between said partial heat sinks, wherein said air discharge means engage in said cross-section of said air duct inside said heat sink device and discharge some air flowing along out of said heat sink device in a direction of areas to be cooled or components on said component carrier.

14. The power unit according to claim 1, wherein said heat sink device has a single continuous heat sink, and at least one recess extending inwards from said outside is provided in said heat sink, wherein said recess takes up between 10% and 30% of said cross-section of said heat sink device, wherein said at least one recess is provided on a side of said heat sink device towards said component carrier or is provided in an area of said heat sink device in which said heat sink device has a solid base element with ribs protruding from it.

15. The power unit according to claim 14, wherein air discharge means are provided in a recess in said single heat sink, said air discharge means being in a manner of a flap or in a manner of an air guide vane, wherein said air discharge means engage into said cross-section of said air duct inside said heat sink device and discharge some of said air flowing along out of said heat sink device in a direction of areas to be cooled or components on said component carrier.

16. The power unit according to claim 13, wherein said air discharge means are designed movable or adjustable in terms of an extent to which said air discharge means engage in said cross-section of said air duct inside said heat sink device.

17. The power unit according to claim 1, wherein an air intake device in a manner of an air guide vane is provided on an outer area of said heat sink device with air passages therein and facing one of said outer walls, wherein said outer area with said air intake device is opposite of components to be cooled.

18. The power unit according to claim 17, wherein said air intake device is movable between a first position, in which said air intake device projects into said free area and diverts air flowing outside said heat sink device and along said air duct into said heat sink device, and a second position, in which said air intake device projects less far into said free area or not at all.

19. The power unit according to claim 17, wherein said air intake device is designed thermally triggerable and self-adjustable depending on a temperature by means of a bimetal actuator.

20. An induction hob having a housing with walls and a power unit according to claim 1, wherein said power unit extends along an outer border area of said housing.
